(19) United States
(12) Patent Application Publication
(10) Pub. No.: US 2022/0269176 A1
(43) Pub. Date: Aug. 25, 2022

(54) COMPOSITION FOR COATING SUBSTRATE WITH LEVEL DIFFERENCE, SAID COMPOSITION CONTAINING COMPOUND HAVING CURABLE FUNCTIONAL GROUP

(71) Applicant: NISSAN CHEMICAL CORPORATION, Tokyo (JP)

(72) Inventors: Hayato HATTORI, Toyama-shi (JP); Hikaru TOKUNAGA, Toyama-shi (JP); Hirokazu NISHIMAKI, Toyama-shi (JP); Makoto NAKAJIMA, Toyama-shi (JP)

(73) Assignee: NISSAN CHEMICAL CORPORATION, Tokyo (JP)

(21) Appl. No.: 17/627,920

(22) PCT Filed: Jun. 22, 2020
(86) PCT No.: PCT/JP2020/024442

§ 371 Date: Jan. 18, 2022

(30) Foreign Application Priority Data
Jul. 18, 2019 (JP) 2019-132883

(51) Int. Cl. G03F 7/11; C09D 7/63; C09D 133/08; G03F 7/09; H01L 21/027

(52) U.S. Cl. CPC G03F 7/11; C09D 7/63; H01L 21/0274; G03F 7/094; C09D 133/08

(57) ABSTRACT

A composition having a multi-level substrate coating composition for forming a coating film having a filling onto a pattern and planarization, wherein the composition includes a compound (A) serving as a main agent, and a solvent, wherein the compound (A) forms the following Formula (A-1), (A-2) and (A-3); In Formulas (A-1), (A-2) and (A-3), a broken line is a bond to the aromatic ring; the aromatic ring forming a polymer skeleton or forming a monomer; and n is an integer of 1 or 2; A chain line is a bond to a carbon chain, alicyclic carbon ring, or aromatic ring forming a polymer skeleton; Q is a single bond, or an organic group having an ether bond, an ester bond, a urethane bond, a C1-3 alkylene bond, or an amide bond; m is 1; and Formula (A-3) does not include Formula (A-1), and the composition is cured photoirradiation or heating.

### TECHNICAL FIELD

The present invention relates to a multi-level substrate coating composition for forming a planarization film on a multi-level substrate through curing by photoirradiation or heating, and a method for producing a laminated substrate that is planarized by using the multi-level substrate coating composition.

### BACKGROUND ART

In recent years, semiconductor integrated circuit devices have been processed with a fine design rule. In order to create still finer resist patterns while using optical lithography technique, exposure wavelengths need to be further shortened.

However, since the depth of focus declines while shortening the exposure wavelengths, the planarity of a coating film formed on a substrate needs to be further advanced. Specifically, a technique for planarization of the film on the substrate has become important for producing a semiconductor device having a fine design rule.

Until now, as to methods of forming planarization films, for example, a method for forming a resist underlayer film under a resist film through photocuring has been disclosed.

For example, there has been disclosed a resist underlayer film-forming composition containing a polymer having an epoxy group or an oxetane group in a side chain and a photo-cationic polymerization initiator, or a resist underlayer film-forming composition containing a polymer having a radical polymerizable ethylenically unsaturated bond and a photo-radical polymerization initiator (see Patent Document 1).

There has also been disclosed a resist underlayer film-forming composition containing a silicon-containing compound having a cationic polymerizable reactive group (e.g., an epoxy group or a vinyl group), a photo-cationic polymerization initiator, and a photo-radical polymerization initiator (see Patent Document 2).

There has also been disclosed a method for producing a semiconductor device using a resist underlayer film containing a polymer having a crosslinkable functional group (e.g., a hydroxy group) in a side chain, a crosslinking agent, and a photoacid generator (see Patent Document 3).

There has also been disclosed a resist underlayer film having an unsaturated bond in a main or side chain, which is not a photo-crosslinked resist underlayer film (see Patent Documents 4 and 5).

There has also been disclosed a resist underlayer film formed of a polymer having an epoxy group in a side chain (see Patent Document 6).

### PRIOR ART DOCUMENTS

### Patent Documents

Patent Document 1: WO 2006/115044

Patent Document 2: WO 2007/066597

Patent Document 3: WO 2008/047638

Patent Document 4: WO 2009/008446

Patent Document 5: JP 2004-533637 A

Patent Document 6: WO 2019/054420

### SUMMARY OF THE INVENTION

### Problems to be Solved by the Invention

A conventional photo-crosslinkable material, for example, a resist underlayer film-forming composition containing a polymer having a thermally crosslinkable functional group such as a hydroxy group, a crosslinking agent, and an acid catalyst (acid generator) may pose the following problem. Specifically, when the composition is heated for being filled into a pattern (e.g., a hole or a trench structure) formed on a substrate, a crosslinking reaction proceeds, thus leading to an increase in viscosity so as to cause insufficient filling into the pattern on the substrate. The composition may also pose a problem in terms of impaired planarity due to occurrence of thermal shrinkage caused by degassing.

Thus, an object of the present invention is to provide a multi-level substrate coating composition for forming a coating film having planarity on a substrate, wherein the composition can achieve sufficient filling onto a pattern and can form a coating film without causing degassing or thermal shrinkage.

### Means for Solving the Problems

A first aspect of the present invention is a multi-level substrate coating composition comprising a compound (A) serving as a main agent, and a solvent, wherein the compound (A) has a partial structure of the following Formula (A-1), (A-2), or (A-3):

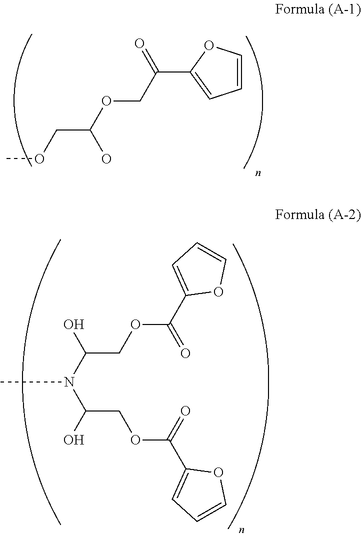

(wherein a broken line is a bond to an aromatic ring; the aromatic ring is an aromatic ring forming a polymer skeleton or an aromatic ring forming a monomer; and n is an integer of 1 to 4)

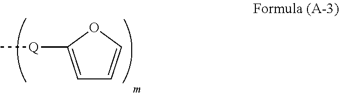

(wherein a chain line is a bond to a carbon chain, alicyclic carbon ring, or aromatic ring forming a polymer skeleton; Q is a single bond, or an organic group having an ether bond, an ester bond, a urethane bond, a C₁₋₃ alkylene bond, or an amide bond; Formula (A-3) does not include Formula (A-1); and m is 1), and the composition is cured by photoirradiation or heating.

A second aspect of the present invention is the multi-level substrate coating composition according to the first aspect, wherein the aromatic ring is a benzene ring, a naphthalene ring, or an anthracene ring.

A third aspect of the present invention is the multi-level substrate coating composition according to the first or second aspect, wherein the polymer containing the aromatic ring is a polymer having a hydroxyaryl novolac structure in which a hydroxyl group is substituted with a partial structure of Formula (A-1) or (A-2).

A fourth aspect of the present invention is the multi-level substrate coating composition according to the first or second aspect, wherein the monomer containing the aromatic ring is a monomer prepared by substitution of a hydroxyl group of the aromatic ring with a partial structure of Formula (A-1) or (A-2).

A fifth aspect of the present invention is the multi-level substrate coating composition according to any one of the first to fourth aspects, wherein the composition further comprises an acid generator.

A sixth aspect of the present invention is the multi-level substrate coating composition according to any one of the first to fifth aspects, wherein the composition further comprises a surfactant.

A seventh aspect of the present invention is a method for producing a coated substrate, the method comprising a step (i) of applying the multi-level substrate coating composition according to any one of the first to sixth aspects to a multi-level substrate; and a step (ii) of exposing the composition applied in the step (i) to light or heating the composition during or after light exposure.

An eighth aspect of the present invention is the method for producing a coated substrate according to the seventh aspect, wherein the method further comprises a step (ia) of heating the multi-level substrate coating composition on the multi-level substrate at a temperature of 70° C. to 400° C. for 10 seconds to five minutes after the step (i) and before the light exposure step (ii).

A ninth aspect of the present invention is the method for producing a coated substrate according to the seventh or eighth aspect, wherein light used for the light exposure in the step (ii) has a wavelength of 150 nm to 700 nm.

A tenth aspect of the present invention is the method for producing a coated substrate according to any one of the seventh to ninth aspects, wherein the dose of exposure light is 10 mJ/cm² to 5,000 mJ/cm² in the step (ii).

An eleventh aspect of the present invention is the method for producing a coated substrate according to the seventh aspect, wherein the composition is heated at a temperature of 100° C. to 500° C. in the step (ii).

A twelfth aspect of the present invention is the method for producing a coated substrate according to any one of the seventh to eleventh aspects, wherein the multi-level substrate has an open area (non-patterned area) and a patterned area of DENSE (dense) and ISO (coarse), and the pattern has an aspect ratio of 0.1 to 100.

A thirteenth aspect of the present invention is the method for producing a coated substrate according to any one of the seventh to twelfth aspects, wherein the multi-level substrate has an open area (non-patterned area) and a patterned area of DENSE (dense) and ISO (coarse), and the difference in coating level (Bias) between the open area and the patterned area is 1 nm to 50 nm.

A fourteenth aspect of the present invention is a method for producing a semiconductor device, the method comprising a step of forming, on a multi-level semiconductor substrate, an underlayer film from the multi-level substrate coating composition according to any one of the first to sixth aspects; a step of forming a resist film on the underlayer film; a step of irradiating the resist film with light or electron beams or heating the resist film during or after irradiation with light or electron beams, and then developing the resist film, to thereby form a resist pattern; a step of etching the underlayer film with the formed resist pattern; and a step of processing the semiconductor substrate with the patterned underlayer film.

A fifteenth aspect of the present invention is the method for producing a semiconductor device according to the fourteenth aspect, wherein the underlayer film forming step comprises a step (i) of applying the multi-level substrate coating composition according to any one of the first to sixth aspects to the multi-level substrate; and a step (ii) of exposing the composition applied in the step (i) to light or heating the composition.

A sixteenth aspect of the present invention is the method for producing a semiconductor device according to the fifteenth aspect, wherein the method further comprises a step (ia) of heating the multi-level substrate coating composition on the multi-level substrate at a temperature of 70° C. to 400° C. for 10 seconds to five minutes after the step (i) and before the light exposure step (ii).

A seventeenth aspect of the present invention is the method for producing a semiconductor device according to the fifteenth or sixteenth aspect, wherein light used for the light exposure in the step (ii) has a wavelength of 150 nm to 700 nm.

An eighteenth aspect of the present invention is the method for producing a semiconductor device according to any one of the fifteenth to seventeenth aspects, wherein the dose of exposure light is 10 mJ/cm² to 5,000 mJ/cm² in the step (ii).

A nineteenth aspect of the present invention is the method for producing a semiconductor device according to the fifteenth aspect, wherein the composition is heated at a temperature of 100° C. to 500° C. in the step (ii).

A twentieth aspect of the present invention is the method for producing a semiconductor device according to any one of the fourteenth to nineteenth aspects, wherein the multi-level substrate has an open area (non-patterned area) and a patterned area of DENSE (dense) and ISO (coarse), and the pattern has an aspect ratio of 0.1 to 100.

A twenty-first aspect of the present invention is the method for producing a semiconductor device according to any one of the fourteenth to twentieth aspects, wherein the multi-level substrate has an open area (non-patterned area) and a patterned area of DENSE (dense) and ISO (coarse), and the underlayer film formed from the multi-level substrate coating composition has a difference in coating level (Bias) between the open area and the patterned area of 1 nm to 50 nm.

A twenty-second aspect of the present invention is a method for producing a semiconductor device, the method comprising a step of forming, on a multi-level semiconductor substrate, an underlayer film from the multi-level substrate coating composition according to any one of the first to sixth aspects; a step of forming a hard mask on the underlayer film; a step of forming a resist film on the hard mask; a step of irradiating the resist film with light or electron beams or heating the resist film during or after irradiation with light or electron beams, and then developing the resist film, to thereby form a resist pattern; a step of etching the hard mask with the formed resist pattern; a step of etching the underlayer film with the patterned hard mask; and a step of processing the semiconductor substrate with the patterned underlayer film.

A twenty-third aspect of the present invention is the method for producing a semiconductor device according to the twenty-second aspect, wherein the underlayer film forming step comprises a step (i) of applying the multi-level substrate coating composition according to any one of the first to sixth aspects to the multi-level substrate; and a step (ii) of exposing the composition applied in the step (i) to light or heating the composition.

A twenty-fourth aspect of the present invention is the method for producing a semiconductor device according to the twenty-third aspect, wherein the method further comprises a step (ia) of heating the multi-level substrate coating composition on the multi-level substrate at a temperature of 70° C. to 400° C. for 10 seconds to five minutes after the step (i) and before the light exposure step (ii).

A twenty-fifth aspect of the present invention is the method for producing a semiconductor device according to the twenty-third or twenty-fourth aspect, wherein light used for the light exposure in the step (ii) has a wavelength of 150 nm to 700 nm.

A twenty-sixth aspect of the present invention is the method for producing a semiconductor device according to any one of the twenty-third to twenty-fifth aspects, wherein the dose of exposure light is 10 mJ/cm² to 5,000 mJ/cm² in the step (ii).

A twenty-seventh aspect of the present invention is the method for producing a semiconductor device according to the twenty-third aspect, wherein the composition is heated at a temperature of 100° C. to 500° C. in the step (ii).

A twenty-eighth aspect of the present invention is the method for producing a semiconductor device according to any one of the twenty-second to twenty-seventh aspects, wherein the multi-level substrate has an open area (non-patterned area) and a patterned area of DENSE (dense) and ISO (coarse), and the pattern has an aspect ratio of 0.1 to 100.

A twenty-ninth aspect of the present invention is the method for producing a semiconductor device according to any one of the twenty-second to twenty-eighth aspects, wherein the multi-level substrate has an open area (non-patterned area) and a patterned area of DENSE (dense) and ISO (coarse), and the underlayer film formed from the multi-level substrate coating composition has a difference in coating level (Bias) between the open area and the patterned area of 1 nm to 50 nm.

### Effects of the Invention

When the multi-level substrate coating composition of the present invention is cured by photoirradiation, the composition is heated at a low temperature, and thus crosslinking reaction does not occur at the temperature. Therefore, sufficient planarity is achieved on the multi-level substrate. Furthermore, a favorable planarization film can be formed through photocuring. Meanwhile, when the composition is cured only by heating, a favorable planarization film is formed, since crosslinking reaction is initiated after sufficient reflow at a high temperature because of a high crosslinking initiation temperature of the crosslinkable group contained in the polymer.

When the multi-level substrate coating composition of the present invention is applied onto a multi-level substrate, a flat film can be formed on the multi-level substrate regardless of an open area (non-patterned area) or a patterned area of DENSE (dense) and ISO (coarse) on the substrate. In the multi-level substrate coating film (planarization film) formed from the multi-level substrate coating composition of the present invention, crosslinking reaction between a crosslinking agent and an acid catalyst does not occur during thermal reflow, since the crosslinking agent is not an essential component of the composition. In the case of photoirradiation, the composition is cured by a photoreaction associated with no degassing, and thus thermal shrinkage does not occur.

Thus, the multi-level substrate coating composition of the present invention can achieve both sufficient filling onto a pattern and good planarity after filling onto the pattern, to thereby form an excellent planarization film.

In addition, the multi-level substrate coating composition of the present invention can be cured by heating or light exposure. In particular, since the composition can be cured only by heating, the composition enables convenient operation and achieves high production efficiency.

### MODES FOR CARRYING OUT THE INVENTION

The present invention is directed to a multi-level substrate coating composition comprising a compound (A) serving as a main agent, and a solvent, wherein the compound (A) has a partial structure of the following Formula (A-1), (A-2), or (A-3):

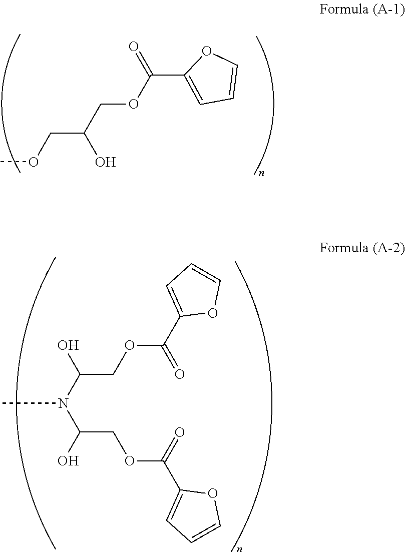

(wherein a broken line is a bond to an aromatic ring; the aromatic ring is an aromatic ring forming a polymer skeleton or an aromatic ring forming a monomer; and n is an integer of 1 or 2)

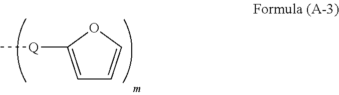

(wherein a chain line is a bond to a carbon chain, alicyclic carbon ring, or aromatic ring forming a polymer skeleton; Q is a single bond, or an organic group having an ether bond, an ester bond, a urethane bond, a C₁₋₃ alkylene bond, or an amide bond; m is 1; and Formula (A-3) does not include Formula (A-1)), and the composition is cured by photoirradiation or heating.

In Formula (A-1), n is an integer of 1 or 2; the broken line is a bond to an aromatic ring; and the aromatic ring is an aromatic ring forming a polymer skeleton or an aromatic ring forming a monomer.

The aforementioned aromatic ring may be a benzene ring, a naphthalene ring, or an anthracene ring.

The polymer containing the aromatic ring may be a polymer having a hydroxyaryl novolac structure in which a hydroxyl group is substituted with a partial structure of Formula (A-1) or (A-2). The aryl group may be an aromatic group derived from benzene or naphthalene. Examples of the polymer include, but are not limited to, those shown below.

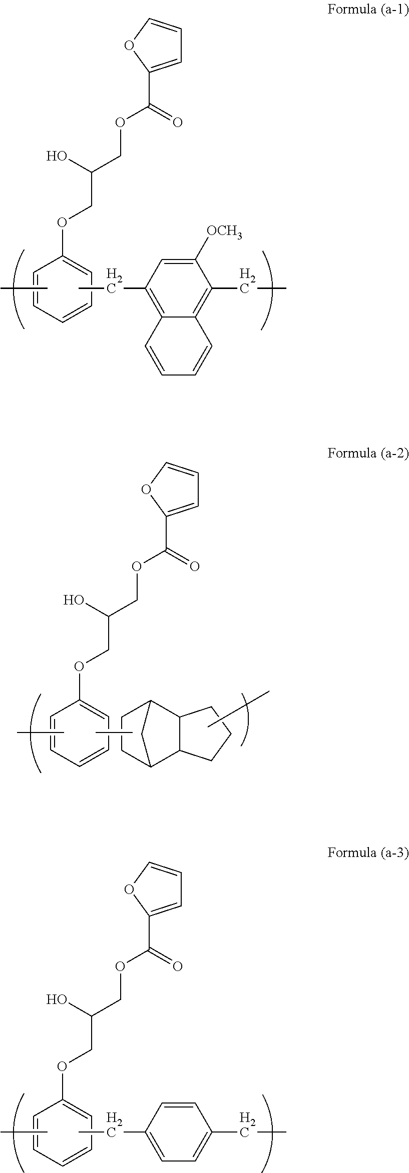

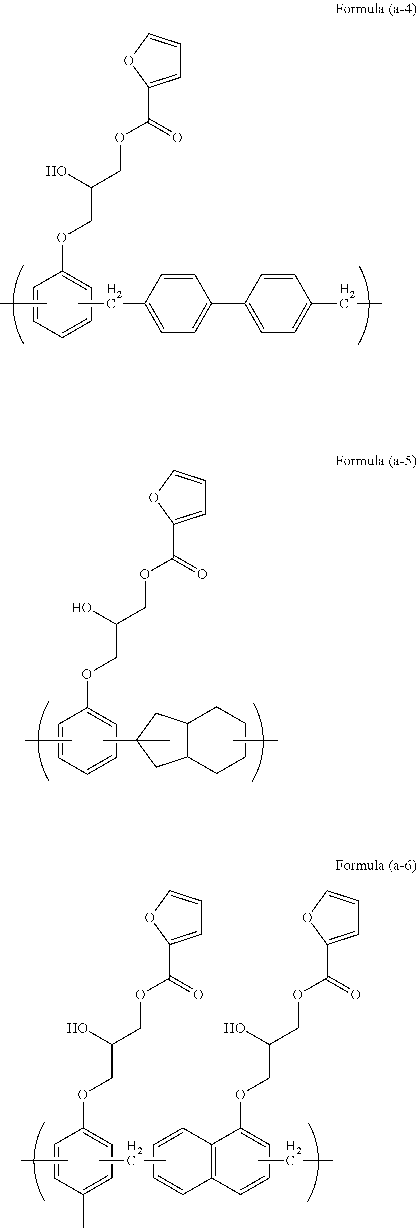

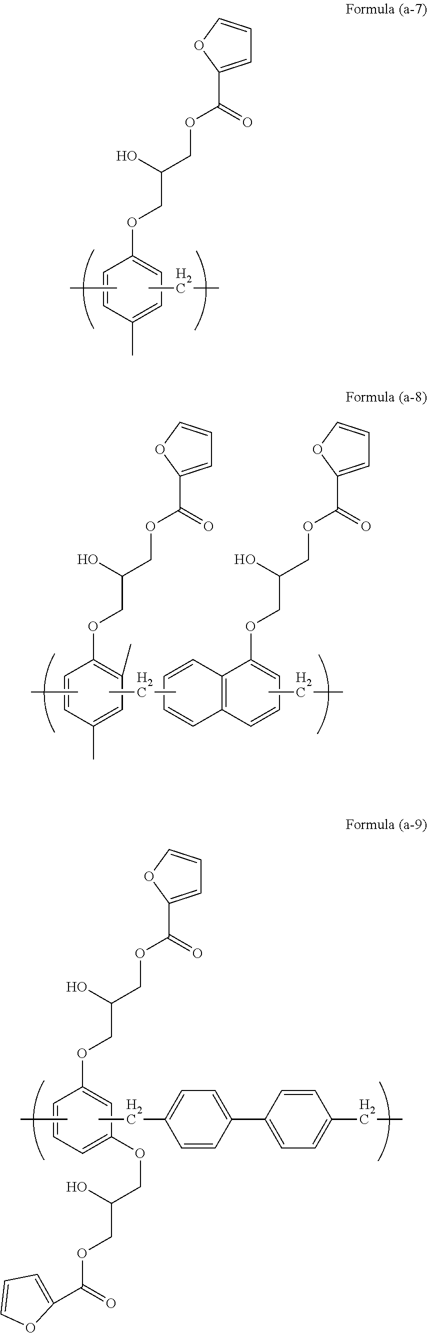

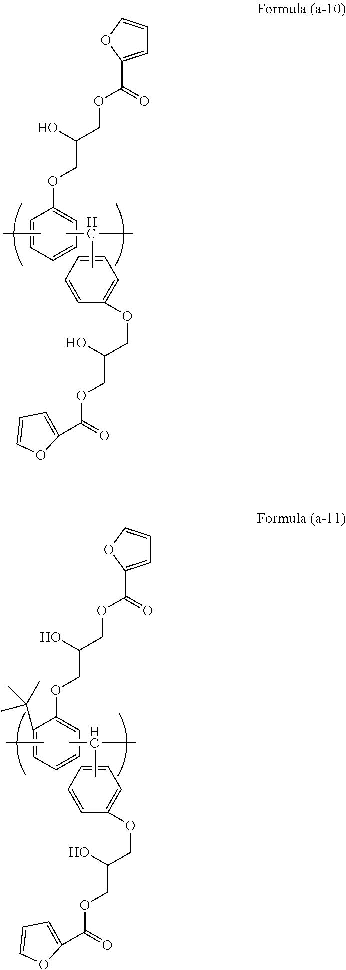

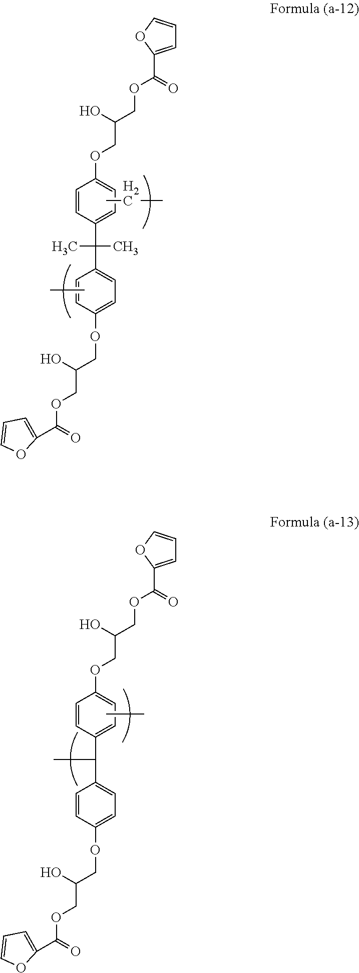

No limitation is imposed on the method for producing each of the polymers of Formulae (a-1) to (a-13). Each polymer is synthesized by any known method; for example, through condensation reaction between an epoxy group of a precursor polymer and 2-furancarboxylic acid.

The aforementioned polymer has a weight average molecular weight of 600 to 1,000,000, or 600 to 200,000, or 1,500 to 15,000.

In the present invention, the monomer containing the aromatic ring may be a monomer in which a glycidyl ether group of the aromatic ring is substituted with a partial structure of Formula (A-1) or (A-2). Examples of the monomer include, but are not limited to, those shown below.

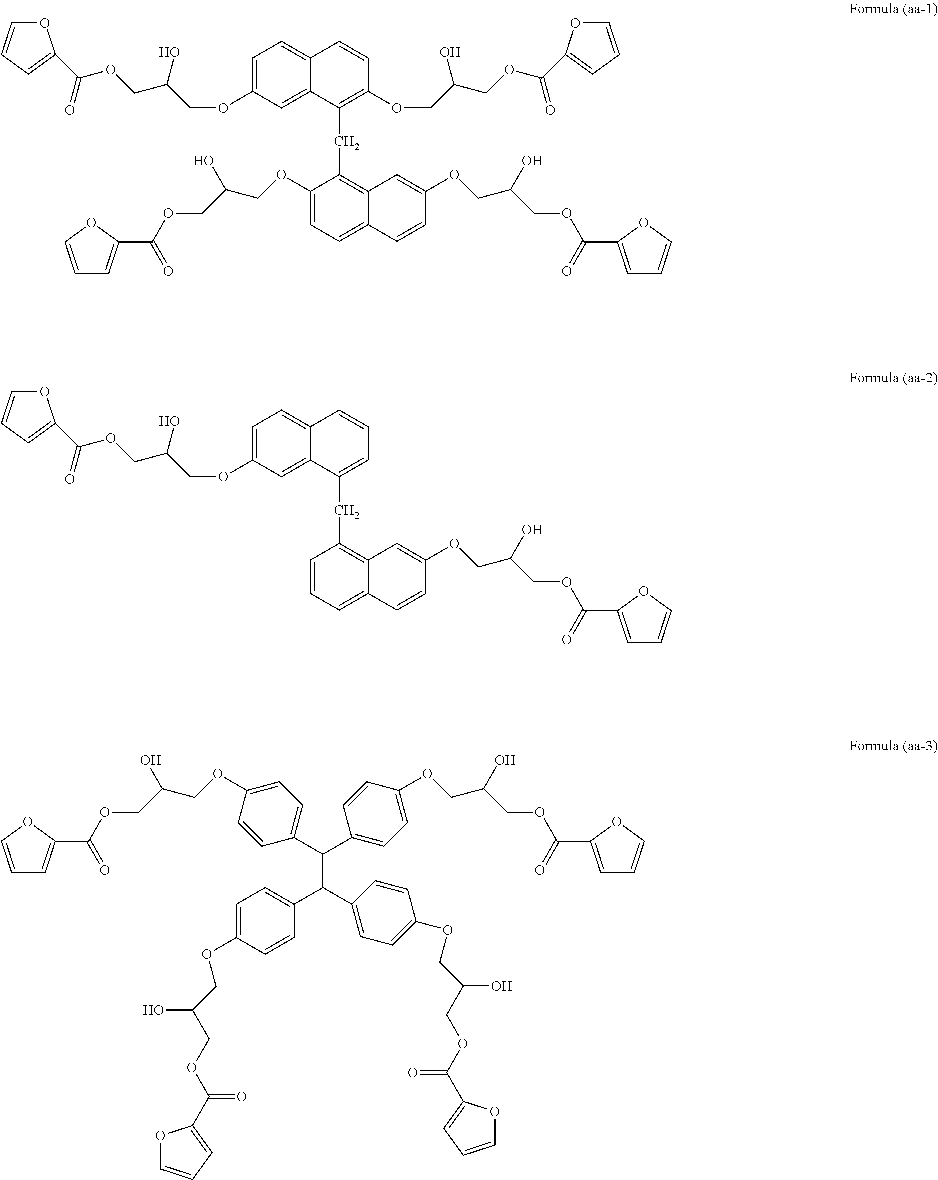 [SMILES: O=C(OCC(O)COc1ccc2ccc(OCC(O)COC(=O)c3ccco3)c(Cc3c(OCC(O)COC(=O)c4ccco4)ccc4ccc(OCC(O)COC(=O)c5ccco5)cc34)c2c1)c1ccco1 ; O=C(OCC(O)COc1ccc2cccc(Cc3cccc4ccc(OCC(O)COC(=O)c5ccco5)cc34)c2c1)c1ccco1 ; O=C(OCC(O)COc1ccc(C(c2ccc(OCC(O)COC(=O)c3ccco3)cc2)C(c2ccc(OCC(O)COC(=O)c3ccco3)cc2)c2ccc(OCC(O)COC(=O)c3ccco3)cc2)cc1)c1ccco1]

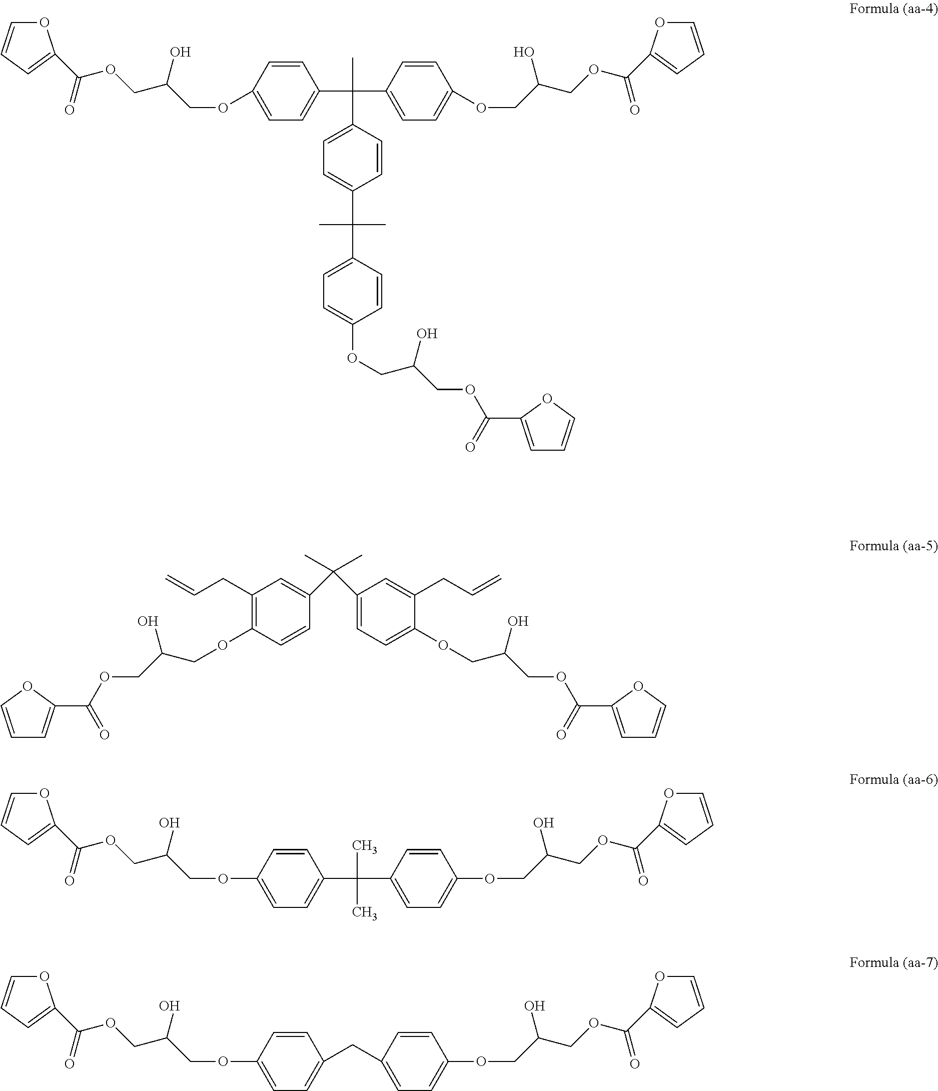 [SMILES: CC(C)(c1ccc(OCC(O)COC(=O)c2ccco2)cc1)c1ccc(C(C)(c2ccc(OCC(O)COC(=O)c3ccco3)cc2)c2ccc(OCC(O)COC(=O)c3ccco3)cc2)cc1 ; C=CCc1cc(C(C)(C)c2ccc(OCC(O)COC(=O)c3ccco3)c(CC=C)c2)ccc1OCC(O)COC(=O)c1ccco1 ; CC(C)(c1ccc(OCC(O)COC(=O)c2ccco2)cc1)c1ccc(OCC(O)COC(=O)c2ccco2)cc1 ; O=C(OCC(O)COc1ccc(Cc2ccc(OCC(O)COC(=O)c3ccco3)cc2)cc1)c1ccco1]

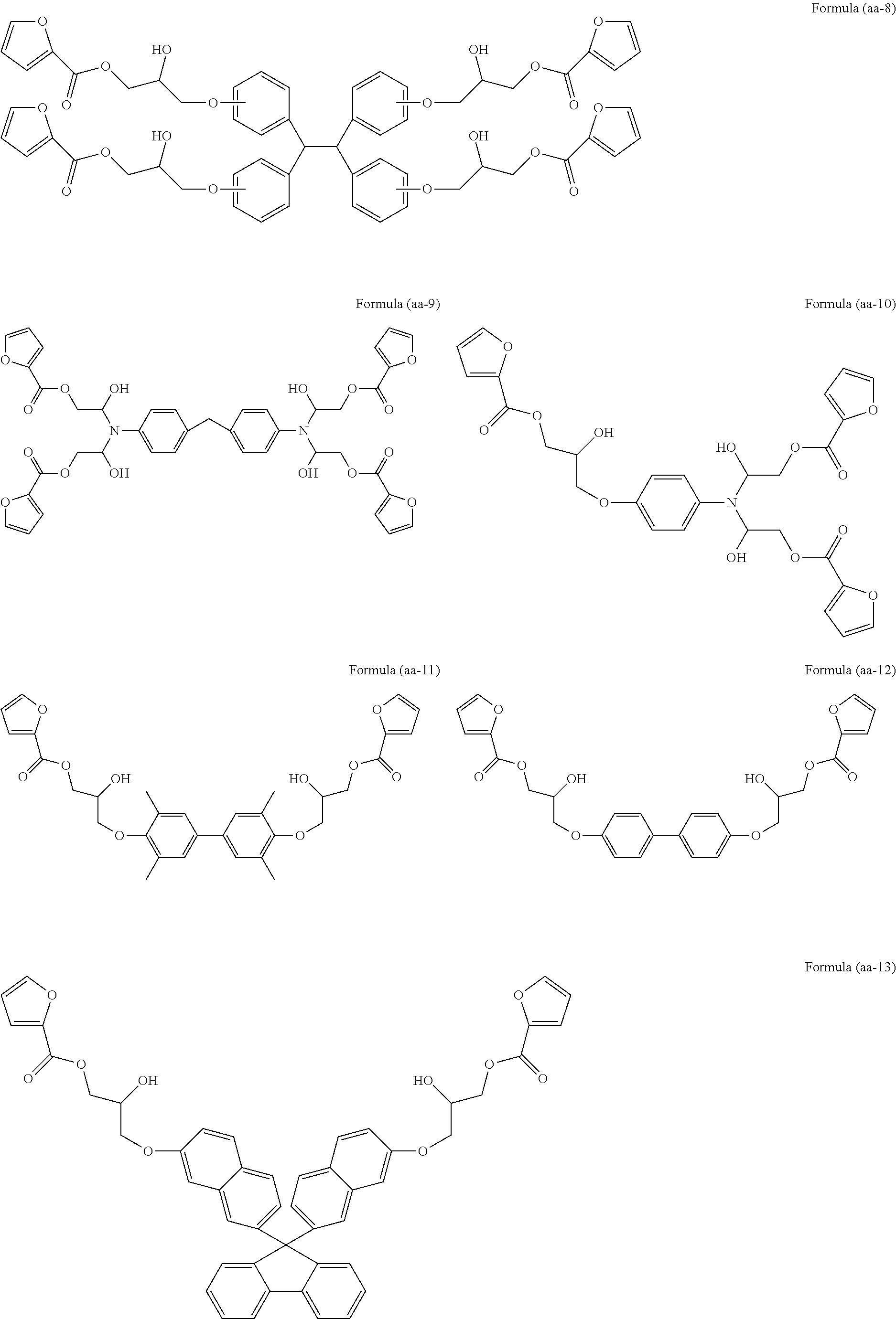

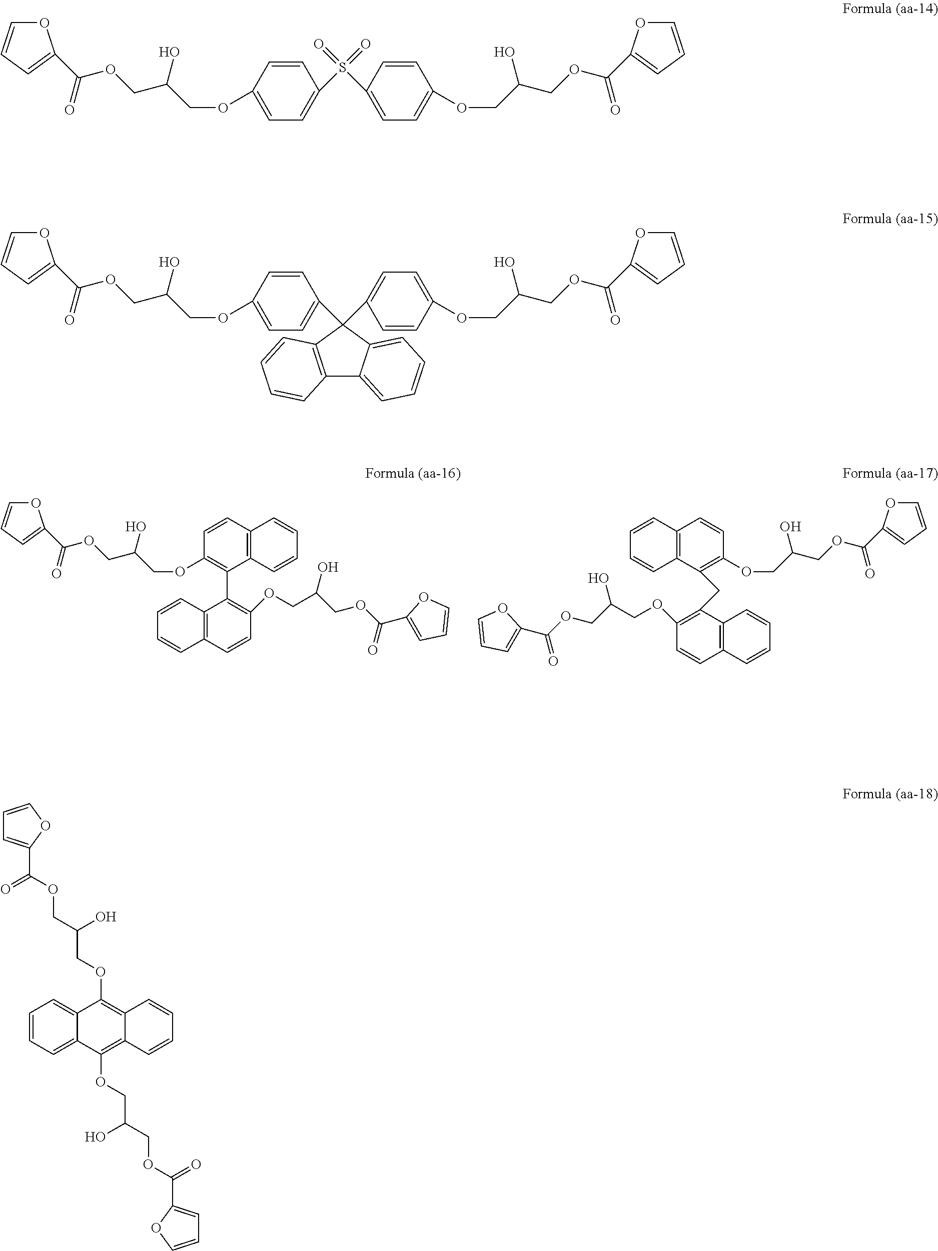

Each of the monomer compounds of Formulae (aa-1) to (aa-18) is synthesized by substitution of an epoxy group of a precursor monomer through condensation with 2-furancarboxylic acid.

The monomer containing the aromatic ring may have a molecular weight of 200 to 10,000, or 200 to 2,000, or 200 to 1,000.

In Formula (A-3), the chain line is a bond to a carbon chain, alicyclic carbon ring, or aromatic ring forming a polymer skeleton. Q is a single bond, or an organic group having an ether bond, an ester bond, a urethane bond, a C₁₋₃ alkylene bond, or an amide bond. Formula (A-3) does not include Formula (A-1). In Formula (A-3), m is 1.

The polymer skeleton and furan may be bonded directly by the aforementioned ether bond (—O—), ester bond (—COO—), urethane bond (—NHCOO—), C₁₋₃ alkylene bond (—CH₂—, —CH₂CH₂—, —CH₂CH₂CH₂—), or amide bond (—CONH—), or may be bonded via an organic group containing any of these linking groups.

For synthesis of the polymer compound of Formula (A-3), a copolymer may be produced from a monomer serving as a raw material thereof and an additional copolymerizable monomer, and the copolymer may be used as the polymer compound of the present invention. Examples of the additional copolymerizable monomer include addition polymerizable monomers, such as acrylic acid esters, methacrylic acid esters, acrylamide, methacrylamide, vinyl compounds, styrene, maleimide, maleic anhydride, and acrylonitrile. In this case, the mass ratio of a unit structure of Formula (A-3) to a unit structure formed of such an addition polymerizable monomer in the resultant polymer compound is 10/1 to 1/10, or 5/1 to 1/5, or 3/1 to 1/3.

The aforementioned polymer compound has a weight average molecular weight (in terms of standard polystyrene) of 100 or more, for example, 1,000 to 200,000, or 1,500 to 50,000, or 3,000 to 50,000, or 4,000 to 30,000. Examples of the polymer compound include those shown below.

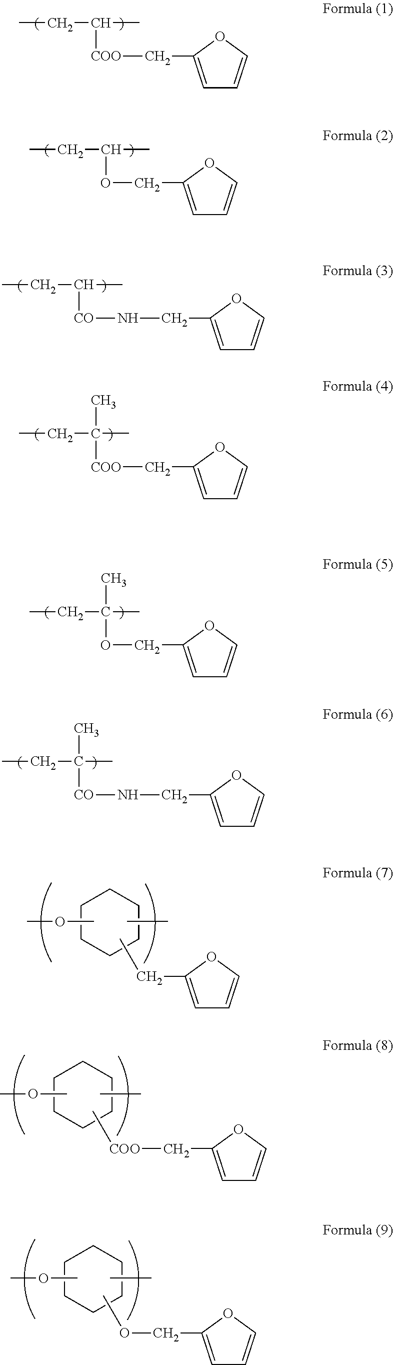

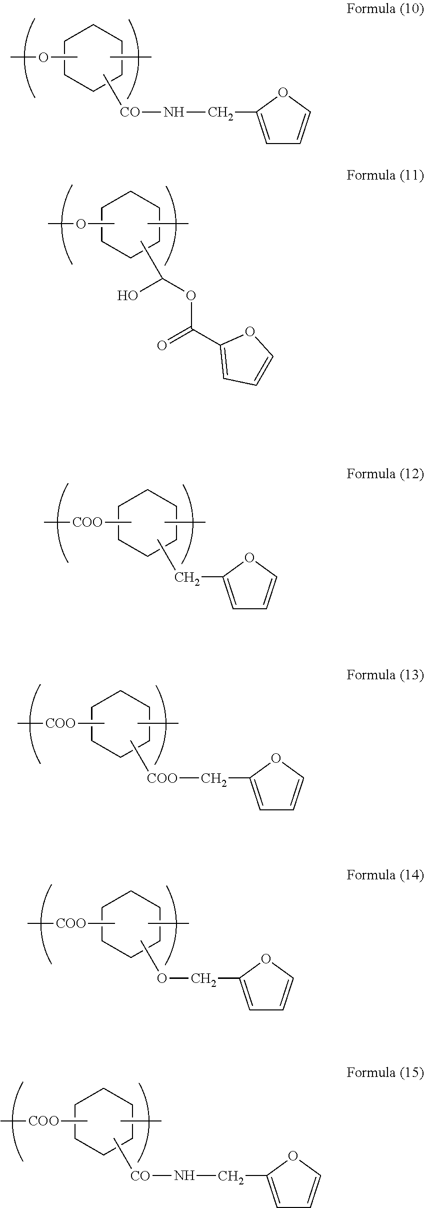

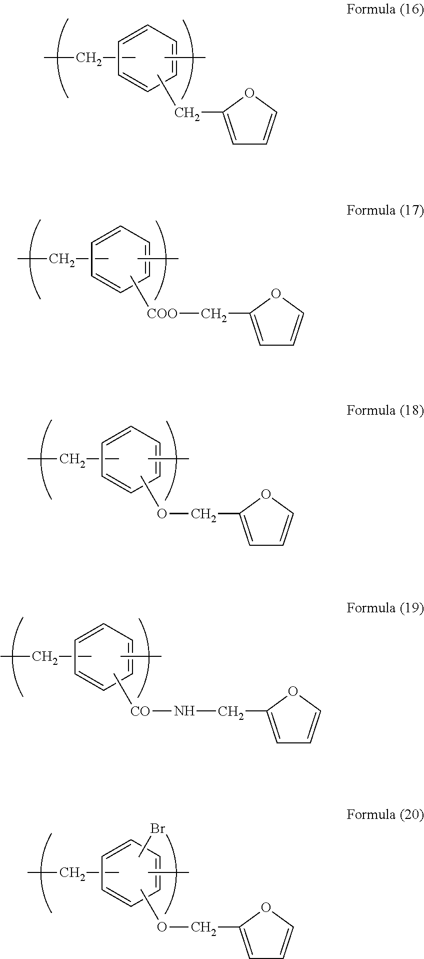

The composition of the present invention may contain an acid generator. The acid generator may be a photoacid generator or a thermal acid generator.

Examples of the photoacid generator include onium salt photoacid generators, such as bis(4-t-butylphenyl)iodonium trifluoromethanesulfonate and triphenylsulfonium trifluoromethanesulfonate; halogen-containing compound photoacid generators, such as phenyl-bis(trichloromethyl)-s-triazine; and sulfonic acid photoacid generators, such as benzoin tosylate and N-hydroxysuccinimide trifluoromethanesulfonate. The amount of the photoacid generator is 0.2 to 5% by mass, or 0.4 to 5% by mass, or 0.4 to 4.9% by mass, or 0.4 to 4.8% by mass, relative to the total solid content.

Examples of the thermal acid generator include 2,4,4,6-tetrabromocyclohexanedienone, benzoin tosylate, 2-nitrobenzyl tosylate, pyridinium p-toluenesulfonate, pyridinium p-hydroxybenzenesulfonate, other organic sulfonic acid alkyl esters, and salts thereof. Examples of commercially available products include K-PURE [registered trademark] CXC-1612, CXC-1614, CXC-1742, CXC-1802, TAG-2678, TAG2681, TAG2689, TAG2690, and TAG2700 (available from King Industries); and SI-45, SI-60, SI-80, SI-100, SI-110, and SI-150 (available from SANSHIN CHEMICAL INDUSTRY CO., LTD.).

These thermal acid generators may be used alone or in combination of two or more species. The amount of the thermal acid generator is, for example, 0.01% by mass to 20% by mass, preferably 0.1% by mass to 10% by mass, relative to the entire mass of the aforementioned furan compound (A).

The multi-level substrate coating composition of the present invention may contain a surfactant. Examples of the surfactant include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenyl ether and polyoxyethylene nonylphenyl ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as EFTOP [registered trademark] EF301, EF303, and EF352 (available from Mitsubishi Materials Electronic Chemicals Co., Ltd.), MEGAFAC [registered trademark] F171, F173, R30, R-30N, R-40, and R-40LM (available from DIC Corporation), Fluorad FC430 and FC431 (available from Sumitomo 3M Limited), Asahi Guard [registered trademark] AG710, and SURFLON [registered trademark] S-382, SC101, SC102, SC103, SC104, SC105, and SC106 (available from Asahi Glass Co., Ltd.); and Organosiloxane Polymer KP341 (available from Shin-Etsu Chemical Co., Ltd.). The composition may contain one species selected from these surfactants, or two or more species selected therefrom in combination. The amount of the surfactant is, for example, 0.01% by mass to 5% by mass, or 0.01% by mass to 2% by mass, or 0.01% by mass to 0.2% by mass, or 0.01% by mass to 0.1% by mass, or 0.01% by mass to 0.09% by mass, relative to the solid content of the multi-level substrate coating composition of the present invention; i.e., the total amount of all components of the composition, except for the amount of the solvent described below.

Examples of the solvent that can be used for dissolving the compound (A) in the present invention include ethylene glycol monomethyl ether, ethylene glycol monoethyl ether, ethylene glycol monobutyl ether, ethylene glycol monoisopropyl ether, ethylene glycol methyl ether acetate, ethylene glycol ethyl ether acetate, methyl cellosolve acetate, ethyl cellosolve acetate, diethylene glycol, diethylene glycol monomethyl ether, diethylene glycol monoethyl ether, diethylene glycol dimethyl ether, diethylene glycol diethyl ether, diethylene glycol monoethyl ether acetate, propylene glycol, propylene glycol monomethyl ether, propylene glycol monobutyl ether, propylene glycol monomethyl ether acetate, propylene glycol monoethyl ether, propylene glycol monoethyl ether acetate, propylene glycol propyl ether acetate, dipropylene glycol monomethyl ether, dipropylene glycol monoethyl ether, triethylene glycol dimethyl ether, toluene, xylene, styrene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 1-octanol, ethylene glycol, hexylene glycol, trimethylene glycol, 1-methoxy-2-buthanol, cyclohexanol, diacetone alcohol, furfuryl alcohol, tetrahydrofurfuryl alcohol, propylene glycol, benzyl alcohol, 1,3-butanediol, 1,4-butanediol, 2,3-butanediol, y-butyrolactone, acetone, methyl isopropyl ketone, diethyl ketone, methyl isobutyl ketone, methyl normal butyl ketone, isopropyl acetate ketone, normal propyl acetate, isobutyl acetate, methanol, ethanol, isopropanol, tert-butanol, allyl alcohol, normal propanol, 2-methyl-2-butanol, isobutanol, normal butanol, 2-methyl-1-butanol, 1-pentanol, 2-methyl-1-pentanol, 2-ethylhexanol, isopropyl ether, 1,4-dioxane, N,N-dimethyl paternmuamide, N,N-dimethylacetamide, N-methylpyrrolidone, 1,3-dimethyl-2-imidazolidinone, dimethyl sulfoxide, and N-cyclohexyl-2-pyrrolidinone. These organic solvents may be used alone or in combination of two or more species.

Next will be described a method for forming a planarization film from the multi-level substrate coating composition of the present invention. Firstly, the multi-level substrate coating composition is applied onto a substrate used for the production of a precise integrated circuit element (e.g., a transparent substrate, such as a silicon/silicon dioxide coating, a glass substrate, or an ITO substrate) by an appropriate coating method using, for example, a spinner or a coater. Thereafter, the composition is baked (heated) or exposed to light, to thereby form a coating film. Specifically, a coated substrate is produced by a method including a step (i) of applying the multi-level substrate coating composition to a multi-level substrate, and a step (ii) of exposing the composition applied in the step (i) to light or heating the composition.

When a spinner is used for application of the composition, the application can be performed at a spinner rotation speed of 100 to 5,000 for 10 to 180 seconds.

The aforementioned substrate may have an open area (non-patterned area) and a patterned area of DENSE (dense) and ISO (coarse), and the pattern may have an aspect ratio of 0.1 to 10 or 0.1 to 100.

The “non-patterned area” refers to an area where a pattern (e.g., a hole or a trench structure) is absent on the substrate. “DENSE (dense)” refers to an area where patterns are densely present on the substrate, and “ISO (coarse)” refers to an area where interpattern distance is large and patterns are scattered on the substrate. The aspect ratio of a pattern is the ratio of the depth of the pattern to the width of the pattern. The pattern depth is generally several hundreds of nm (e.g., about 100 to 300 nm). DENSE (dense) is an area where patterns of about several tens of nm (e.g., 30 to 80 nm) are densely present at intervals of about 100 nm. ISO (coarse) is an area where patterns of several hundreds of nm (e.g., about 200 to 1,000 nm) are scattered.

The multi-level substrate coating film (planarization film) preferably has a thickness of 0.01 μm to 3.0 μm. After application of the composition and before photoirradiation thereof, a step (ia) of heating the composition may be performed at 70° C. to 400° C. or at 100° C. to 250° C. for 10 seconds to five minutes or for 30 seconds to two minutes. This heating causes the reflow of the multi-level substrate coating composition to thereby form a flat multi-level substrate coating film (planarization film).

The exposure light used in the step (ii) is actinic rays, such as near-ultraviolet rays or far-ultraviolet rays; for example, light having a wavelength of 248 nm (KrF laser beam), 193 nm (ArF laser beam), 172 nm (xenon excimer light), or 157 nm (F₂ laser beam). The light exposure can be performed with ultraviolet light having a wavelength of 150 nm to 700 nm, preferably a wavelength of 172 nm.

The light exposure is performed for crosslinking of the multi-level substrate coating film (planarization film). In the step (ii), the dose of the exposure light may be 10 mJ/cm² to 3,000 mJ/cm² or 10 mJ/cm² to 5,000 mJ/cm². Photoreaction occurs at an exposure dose within such a range, leading to formation of a crosslink, resulting in achievement of solvent resistance.

In the step (ii), the multi-level substrate coating film (planarization film) may be crosslinked only by heating without photoirradiation. The heating is preferably performed at a temperature of 100° C. to 500° C. or 200° C. to 400° C. An acid is generated and curing reaction occurs at a temperature falling within this range, whereby solvent resistance is achieved.

In the thus-formed multi-level substrate coating film (planarization film), the Bias (difference in coating level) is preferably zero between the open area and the patterned area. The planarization can be performed so that the Bias falls within a range of 1 nm to 50 nm or 1 nm to 25 nm. The Bias between the open area and the DENSE area is about 15 nm to 20 nm, and the Bias between the open area and the ISO area is about 1 nm to 10 nm.

The multi-level substrate coating film (planarization film) produced by the method of the present invention can be coated with a resist film, and the resist film can be exposed to light and developed by a lithography process, to thereby form a resist pattern. The substrate can be processed with the resist pattern. In this case, the multi-level substrate coating film (planarization film) is a resist underlayer film, and the multi-level substrate coating composition is a resist underlayer film-forming composition.

A resist can be applied onto the resist underlayer film, and the resist can be irradiated with light or electron beams through a predetermined mask, followed by development, rinsing, and drying, to thereby form a good resist pattern. If necessary, post exposure bake (PEB) may be performed after the irradiation with light or electron beams. The resist underlayer film at a portion where the resist film has been developed and removed in the aforementioned step can be removed by dry etching, to thereby form a desired pattern on the substrate.

The resist used in the present invention is a photoresist or an electron beam resist.

In the present invention, the photoresist applied onto the resist underlayer film for lithography may be either of negative and positive photoresists. Examples of the photoresist include a positive photoresist formed of a novolac resin and a 1,2-naphthoquinone diazide sulfonic acid ester; a chemically amplified photoresist formed of a binder having a group that decomposes with an acid to thereby increase an alkali dissolution rate and a photoacid generator; a chemically amplified photoresist formed of an alkali-soluble binder, a low-molecular-weight compound that decomposes with an acid to thereby increase the alkali dissolution rate of the photoresist, and a photoacid generator; a chemically amplified photoresist formed of a binder having a group that decomposes with an acid to thereby increase an alkali dissolution rate, a low-molecular-weight compound that decomposes with an acid to thereby increase the alkali dissolution rate of the photoresist, and a photoacid generator; and a photoresist having an Si atom-containing skeleton. Specific examples of the photoresist include trade name APEX-E available from Rohm and Haas Company.

In the present invention, the electron beam resist applied onto the resist underlayer film for lithography is, for example, a composition containing a resin having an Si—Si bond in a main chain and an aromatic ring at a terminal, and an acid generator that generates an acid through irradiation with electron beams; or a composition containing poly(p-hydroxystyrene) wherein a hydroxyl group is substituted with an N-carboxyamine-containing organic group, and an acid generator that generates an acid through irradiation with electron beams. In the latter electron beam resist composition, an acid generated from the acid generator through irradiation with electron beams reacts with an N-carboxyaminoxy group at a side chain of the polymer, and the polymer side chain decomposes into a hydroxyl group, exhibits alkali solubility, and dissolves in an alkaline developer, to thereby form a resist pattern. Examples of the acid generator that generates an acid through irradiation with electron beams include halogenated organic compounds, such as 1,1-bis[p-chlorophenyl]-2,2,2-trichloroethane, 1,1-bis[p-methoxyphenyl]-2,2,2-trichloroethane, 1,1-bis[p-chlorophenyl]-2,2-dichloroethane, and 2-chloro-6-(trichloromethyl)pyridine; onium salts, such as triphenylsulfonium salts and diphenyliodonium salts; and sulfonic acid esters, such as nitrobenzyl tosylate and dinitrobenzyl tosylate.

The exposure light used for the aforementioned photoresist is actinic rays, such as near-ultraviolet rays, far-ultraviolet rays, or extreme-ultraviolet rays (e.g., EUV, wavelength: 13.5 nm); for example, light having a wavelength of 248 nm (KrF laser beam), 193 nm (ArF laser beam), or 172 nm. No particular limitation is imposed on the usable photoirradiation method, so long as the method can generate an acid from a photoacid generator contained in the resist film. The dose of the exposure light is 1 to 5,000 mJ/cm², or 10 to 5,000 mJ/cm², or 10 to 1,000 mJ/cm².

The electron beam resist can be irradiated with electron beams by using, for example, an electron beam irradiation apparatus.

Examples of the developer for the resist film having the resist underlayer film formed from the multi-level substrate coating composition of the present invention include aqueous solutions of alkalis, for example, inorganic alkalis, such as sodium hydroxide, potassium hydroxide, sodium carbonate, sodium silicate, sodium metasilicate, and aqueous ammonia, primary amines, such as ethylamine and n-propylamine, secondary amines, such as diethylamine and di-n-butylamine, tertiary amines, such as triethylamine and methyldiethylamine, alcoholamines, such as dimethylethanolamine and triethanolamine, quaternary ammonium salts, such as tetramethylammonium hydroxide, tetraethylammonium hydroxide, and choline, and cyclic amines, such as pyrrole and piperidine. The developer to be used may be prepared by addition of an appropriate amount of an alcohol (e.g., isopropyl alcohol) or a surfactant (e.g., a nonionic surfactant) to any of the aforementioned aqueous alkali solutions. Among these developers, quaternary ammonium salts are preferred, and tetramethylammonium hydroxide and choline are more preferred.

The developer may be an organic solvent. Examples of the organic solvent include methyl acetate, butyl acetate, ethyl acetate, isopropyl acetate, amyl acetate, isoamyl acetate, ethyl methoxyacetate, ethyl ethoxyacetate, propylene glycol monomethyl ether, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Such a developer may further contain, for example, a surfactant. The development is performed under appropriately determined conditions; i.e., a temperature of 5 to 50° C. and a time of 10 to 600 seconds.

In the present invention, a semiconductor device can be produced through a step of forming a resist underlayer film on a semiconductor substrate from the resist underlayer film-forming composition; a step of forming a resist film on the resist underlayer film; a step of irradiating the resist film with light or electron beams, and developing the resist film, to thereby form a resist pattern; a step of etching the resist underlayer film with the resist pattern; and a step of processing the semiconductor substrate with the patterned resist underlayer film.

In the future, the formation of a finer resist pattern will cause a problem in terms of resolution and a problem in that the resist pattern collapses after development, and a decrease in the thickness of a resist will be demanded. Thus, it is difficult to form a resist pattern having a thickness sufficient for processing of a substrate. This requires a process for imparting a mask function, during the substrate processing, not only to the resist pattern, but also to a resist underlayer film that is formed between the resist film and the semiconductor substrate to be processed. The resist underlayer film required for such a process is not a conventional resist underlayer film having a high etching rate, but a resist underlayer film for lithography having a selection ratio of dry etching rate similar to that of the resist film, a resist underlayer film for lithography having a smaller selection ratio of dry etching rate than the resist film, or a resist underlayer film for lithography having a smaller selection ratio of dry etching rate than the semiconductor substrate. Such a resist underlayer film may be provided with an anti-reflective performance; i.e., the film may also have the function of a conventional anti-reflective coating.

Meanwhile, a finer resist pattern has started to be formed by using a process for making a resist pattern and a resist underlayer film thinner than the pattern width during the resist development by dry etching of the resist underlayer film. The resist underlayer film required for such a process is not a conventional anti-reflective coating having a high etching rate, but a resist underlayer film having a selection ratio of dry etching rate similar to that of the resist film. Such a resist underlayer film may be provided with an anti-reflective performance; i.e., the film may also have the function of a conventional anti-reflective coating.

In the present invention, after formation of the resist underlayer film of the present invention on a substrate, a resist may be applied directly to the resist underlayer film, or if necessary, the resist may be applied after formation of one to several layers of coating material on the resist underlayer film. This process reduces the pattern width of the resist film. Thus, even when the resist film is thinly applied for prevention of pattern collapse, the substrate can be processed with an appropriately selected etching gas.

Specifically, a semiconductor device can be produced through a step of forming a resist underlayer film on a semiconductor substrate from the resist underlayer film-forming composition; a step of forming, on the resist underlayer film, a hard mask from a coating material containing, for example, a silicon component or a hard mask (e.g., from silicon nitride oxide) by vapor deposition; a step of forming a resist film on the hard mask; a step of forming a resist pattern by irradiation with light or electron beams and development; a step of etching the hard mask with the resist pattern by using a halogen-containing gas; a step of etching the resist underlayer film with the patterned hard mask by using an oxygen-containing gas or a hydrogen-containing gas; and a step of processing the semiconductor substrate with the patterned resist underlayer film by using a halogen-containing gas.

In consideration of the effect of the multi-level substrate coating composition of the present invention as an anti-reflective coating, since the light-absorbing moiety is incorporated into the skeleton of the film, the film does not diffuse any substance in the photoresist during heating and drying. The coating film exhibits high anti-reflective effect, since the light-absorbing moiety has sufficiently high light absorption performance.

The multi-level substrate coating composition of the present invention has high thermal stability, and thus can prevent pollution of an upper-layer film caused by a decomposed substance during baking. Also, the composition can provide a temperature margin in a baking step.

Depending on process conditions, the multi-level substrate coating composition of the present invention can be used as a film having the function of preventing light reflection and the function of preventing the interaction between the substrate and the photoresist or preventing the adverse effect, on the substrate, of a material used for the photoresist or a substance generated during the exposure of the photoresist to light.

### EXAMPLES

### Synthesis Example 1

A two-necked flask was charged with 5 g of tetrahydrofurfuryl acrylate (available from Tokyo Chemical Industry Co., Ltd.), 3.01 g of methyl methacrylate (available from Tokyo Chemical Industry Co., Ltd.), 0.42 g of 2,2′-azobis(methyl isobutyrate) (available from Tokyo Chemical Industry Co., Ltd.), and 48 g of propylene glycol monomethyl ether acetate. Thereafter, the resultant mixture was heated to 120° C. and stirred for about six hours. After completion of the reaction, the resultant polymer solution was added dropwise to methanol (available from Kanto Chemical Co., Inc.) for reprecipitation. The resultant precipitate was subjected to suction filtration, and then the filtrate was dried under reduced pressure at 60° C. overnight, to thereby prepare 5 g of compound 1 resin. The resultant compound was found to have a weight average molecular weight Mw of 6,500 as estimated by GPC in terms of polystyrene.

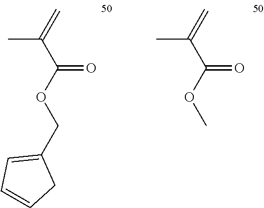

### Synthesis Example 2

A two-necked flask was charged with 7 g of JER-1031S (product name, available from Mitsubishi Chemical Corporation) (tetraphenylethane epoxy resin), 4.1 g of 2-furancarboxylic acid (available from Tokyo Chemical Industry Co., Ltd.), 0.006 g of tetrabutylphosphonium bromide (available from Tokyo Chemical Industry Co., Ltd.), and 26 g of propylene glycol monomethyl ether acetate. Thereafter, the resultant mixture was heated to 100° C. and stirred for about six hours. To the resultant mixture were added 11 g of a cation-exchange resin (product name: DOWEX [registered trademark] 550A, available from MUROMACHI TECHNOS CO., LTD.) and 11 g of an anion-exchange resin (product name: Amberlite [registered trademark] 15JWET, available from ORGANO CORPORATION), and the mixture was subjected to ion-exchange treatment at room temperature for four hours. The ion-exchange resins were then separated to thereby prepare compound 2 solution. The resultant compound was found to have a weight average molecular weight Mw of 1,600 as determined by GPC in terms of polystyrene.

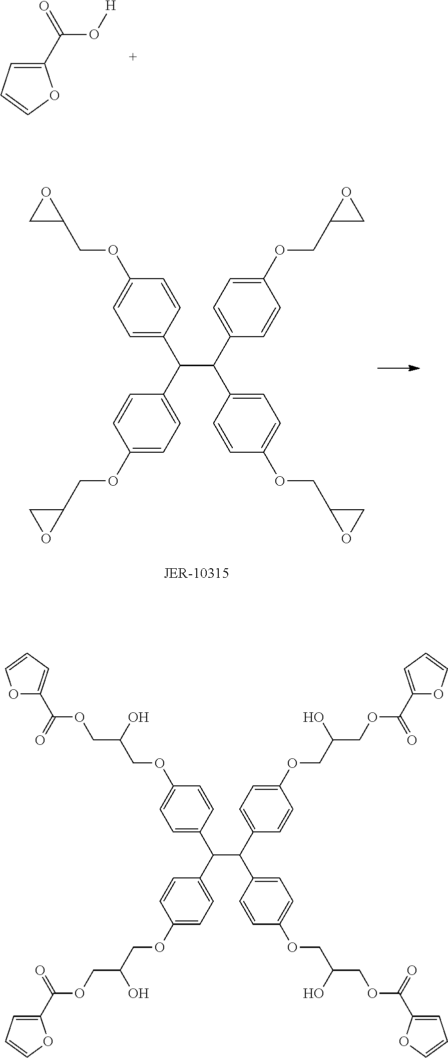 [SMILES: O=C(O)c1ccco1 ; c1cc(C(c2ccc(OCC3CO3)cc2)C(c2ccc(OCC3CO3)cc2)c2ccc(OCC3CO3)cc2)ccc1OCC1CO1 ; O=C(OCC(O)COc1ccc(C(c2ccc(OCC(O)COC(=O)c3ccco3)cc2)C(c2ccc(OCC(O)COC(=O)c3ccco3)cc2)c2ccc(OCC(O)COC(=O)c3ccco3)cc2)cc1)c1ccco1]

### Comparative Synthesis Example 3

In a two-necked flask, 40.0 g of EHPE 3150 (trade name, available from Daicel Corporation) (1,2-epoxy-4-(2-oxylanyl)cyclohexane adduct of 2,2-bis(hydroxymethyl)-1-butanol), 20.3 g of 9-anthracenecarboxylic acid, and 13.7 g of benzoic acid were dissolved in 302.0 g of propylene glycol monomethyl ether. Thereafter, 1.5 g of benzyltriethylammonium was added to the solution, and the mixture was refluxed for 24 hours, to thereby allow reaction to proceed. To the resultant mixture were added 11 g of a cation-exchange resin (product name: DOWEX [registered trademark] 550A, available from MUROMACHI TECHNOS CO., LTD.) and 11 g of an anion-exchange resin (product name: Amberlite [registered trademark] 15JWET, available from ORGANO CORPORATION), and the mixture was subjected to ion-exchange treatment at room temperature for four hours. The ion-exchange resins were then separated to thereby prepare compound 3 solution. The resultant compound was found to have a weight average molecular weight Mw of 4,100 as determined by GPC in terms of polystyrene.

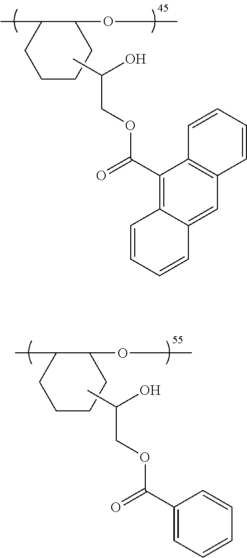

### Example 1

Firstly, 0.95 g of the resin prepared in Synthesis Example 1 was mixed with 0.95 g of propylene glycol monomethyl ether containing 5% TPS-Tf (available from Toyo Gosei Co., Ltd., photoacid generator), 0.09 g of propylene glycol monomethyl ether acetate containing 1% surfactant (product name: MEGAFAC [trade name] R-40, available from DIC Corporation, fluorine-containing surfactant), 1.8 g of propylene glycol monomethyl ether, and 6.2 g of propylene glycol monomethyl ether acetate. Thereafter, the resultant mixture was filtered with a polytetrafluoroethylene-made micro filter (pore size: 0.1 μm) to thereby prepare a solution of a resist underlayer film-forming composition.

### Example 2

Firstly, 8.4 g of the resin solution prepared in Synthesis Example 2 (solid content: 20.4%) was mixed with 1.71 g of propylene glycol monomethyl ether containing 5% TPS-Tf (available from Toyo Gosei Co., Ltd., photoacid generator), 0.17 g of propylene glycol monomethyl ether acetate containing 1% surfactant (product name: MEGAFAC [trade name] R-40, available from DIC Corporation, fluorine-containing surfactant), 2.4 g of propylene glycol monomethyl ether, and 2.3 g of propylene glycol monomethyl ether acetate. Thereafter, the resultant mixture was filtered with a polytetrafluoroethylene-made micro filter (pore size: 0.1 μm) to thereby prepare a solution of a resist underlayer film-forming composition.

### Example 3

Firstly, 8.4 g of the resin solution prepared in Synthesis Example 2 (solid content: 20.4%) was mixed with 1.71 g of propylene glycol monomethyl ether containing 5% TAG 2689 (trade name, available from King (USA), component: quaternary ammonium salt of trifluoromethanesulfonic acid), 0.17 g of propylene glycol monomethyl ether acetate containing 1% surfactant (product name: MEGAFAC [trade name] R-40, available from DIC Corporation, fluorine-containing surfactant), 2.4 g of propylene glycol monomethyl ether, and 2.3 g of propylene glycol monomethyl ether acetate. Thereafter, the resultant mixture was filtered with a polytetrafluoroethylene-made micro filter (pore size: 0.1 μm) to thereby prepare a solution of a resist underlayer film-forming composition.

### Example 4

Firstly, 8.4 g of the resin solution prepared in Synthesis Example 2 (solid content: 20.4%) was mixed with 1.71 g of propylene glycol monomethyl ether containing 5% pyridinium p-hydroxybenzenesulfonate, 0.17 g of propylene glycol monomethyl ether acetate containing 1% surfactant (product name: MEGAFAC [trade name] R-40, available from DIC Corporation, fluorine-containing surfactant), 2.4 g of propylene glycol monomethyl ether, and 2.3 g of propylene glycol monomethyl ether acetate. Thereafter, the resultant mixture was filtered with a polytetrafluoroethylene-made micro filter (pore size: 0.1 μm) to thereby prepare a solution of a resist underlayer film-forming composition.

### Comparative Example 1

Firstly, 1.0 g of the resin prepared in Synthesis Example 1 was mixed with 0.1 g of propylene glycol monomethyl ether acetate containing 1% surfactant (product name: MEGAFAC [trade name] R-40, available from DIC Corporation, fluorine-containing surfactant), 2.7 g of propylene glycol monomethyl ether, and 6.2 g of propylene glycol monomethyl ether acetate. Thereafter, the resultant mixture was filtered with a polytetrafluoroethylene-made micro filter (pore size: 0.1 μm) to thereby prepare a solution of a resist underlayer film-forming composition.

### Comparative Example 2

Firstly, 8.8 g of the resin prepared in Synthesis Example 2 was mixed with 0.2 g of propylene glycol monomethyl ether acetate containing 1% surfactant (product name: MEGAFAC [trade name] R-40, available from DIC Corporation, fluorine-containing surfactant), 2.1 g of propylene glycol monomethyl ether, and 4.0 g of propylene glycol monomethyl ether acetate. Thereafter, the resultant mixture was filtered with a polytetrafluoroethylene-made micro filter (pore size: 0.1 μm) to thereby prepare a solution of a resist underlayer film-forming composition.

### Comparative Example 3

Firstly, 4.9 g of the resin solution prepared in Comparative Synthesis Example 3 (solid content: 16.0%) was mixed with 0.2 g of tetramethoxymethyl glycoluril, 0.2 g of propylene glycol monomethyl ether containing 5% pyridinium p-toluenesulfonate, 0.08 g of propylene glycol monomethyl ether acetate containing 1% surfactant (product name: MEGAFAC [trade name] R-40, available from DIC Corporation, fluorine-containing surfactant), 2.1 g of propylene glycol monomethyl ether, and 2.6 g of propylene glycol monomethyl ether acetate. Thereafter, the resultant mixture was filtered with a polytetrafluoroethylene-made micro filter (pore size: 0.1 μm) to thereby prepare a solution of a resist underlayer film-forming composition.

(Thermal Curing Test)

Each of the resist underlayer film-forming compositions prepared in Examples 3 and 4 and Comparative Examples 1 and 2 was applied onto a silicon wafer with a spin coater. The silicon wafer was heated on a hot plate at 300° C. for 60 seconds, to thereby form a resist underlayer film having a thickness of 200 nm. For evaluation of solvent releasability, the baked coating film was immersed in a solvent mixture of propylene glycol monomethyl ether and propylene glycol monomethyl ether acetate (7:3) for one minute, spin-dried, and then baked at 100° C. for 60 seconds. The thickness of the resultant film was measured to thereby calculate film remaining rate (Table 1).

In Examples 3 and 4, the film remaining rate was 100%, which was attributed to solvent resistance resulting from curing reaction by the effect of an acid generated through heating. In contrast, the film remaining rate was 0% in Comparative Examples 1 and 2.

TABLE 1

| Resist underlayer film-forming composition | Film remaining rate |
|---|---|
| Example 3 | 100% |
| Example 4 | 100% |
| Comparative Example 1 | 0% |
| Comparative Example 2 | 0% |

(Photocuring Test)

Each of the resist underlayer film-forming compositions prepared in Examples 1 and 2 and Comparative Examples 1 and 2 was applied onto a silicon wafer with a spin coater. The silicon wafer was heated on a hot plate at 170° C. for 60 seconds, to thereby form a resist underlayer film having a thickness of 150 nm. The resist underlayer film was irradiated with ultraviolet rays at 500 mJ/cm² by using an ultraviolet irradiation apparatus including a UV irradiation unit (172 nm) available from USHIO INC., and then heated on a hot plate at 160° C. for 60 seconds, to thereby determine solvent releasability with photoirradiation (ultraviolet irradiation). For evaluation of solvent releasability, the ultraviolet-irradiated coating film was immersed in a solvent mixture of propylene glycol monomethyl ether and propylene glycol monomethyl ether acetate (7:3) for one minute, spin-dried, and then baked at 100° C. for 60 seconds. Thereafter, the thickness of the film was measured to thereby calculate film remaining rate (Table 2).

In Examples 1 and 2, the film remaining rate was 100%, which was attributed to solvent resistance resulting from curing reaction by the effect of an acid generated through photoirradiation. In contrast, the film remaining rate was 0% in Comparative Examples 1 and 2.

TABLE 2

| Resist underlayer film-forming composition | Film remaining rate |
|---|---|
| Example 1 | 100% |
| Example 2 | 100% |
| Comparative Example 1 | 7% |
| Comparative Example 2 | 0% |

(Evaluation of Planarity and Fillability on Multi-Level Substrate)

For evaluation of planarity on a multi-level substrate, the thicknesses of portions of a coating film were compared on an SiO₂ substrate having a thickness of 200 nm and having a dense patterned area (DENSE) (trench width: 50 nm, pitch: 100 nm) and a non-patterned open area (OPEN). Each of the resist underlayer film-forming compositions prepared in Examples 1 and 2 was applied onto the aforementioned substrate with a spin coater, and then heated on a hot plate at 170° C. for 60 seconds, to thereby form a resist underlayer films (thickness: 150 nm and 200 nm). The resist underlayer film was irradiated with ultraviolet rays at 500 mJ/cm² by using an ultraviolet irradiation apparatus including a UV irradiation unit (172 nm) available from USHIO INC., and then heated on a hot plate at 160° C. for 60 seconds. Each of the resist underlayer film-forming compositions prepared in Examples 3 and 4 and Comparative Example 3 was applied onto the aforementioned substrate with a spin coater, and then heated on a hot plate at 215° C. and 300° C. for 60 seconds. The planarity of the substrate was evaluated by observation with a scanning electron microscope (S-4800) available from Hitachi High-Technologies Corporation, and by measurement of the difference between the thickness of the multi-level substrate at the dense area (patterned area) and that at the open area (non-patterned area) (i.e., the difference in coating level between the dense area and the open area, which is called “Bias”). The term “planarity” refers to the case where a small difference is present between the thicknesses of portions of the coating film applied onto the patterned area (dense area) and the non-patterned area (open area); i.e., ISO-DENSE Bias is small (Table 3).

In Examples 1 and 2, since crosslinking reaction does not occur at 170° C., sufficient reflow properties are achieved at this stage, and the multi-level substrate exhibits sufficient planarity. Furthermore, a favorable planarization film can be formed through photocuring. In Examples 3 and 4, since the crosslinkable group contained in the polymer exhibits high crosslinking initiation temperature, crosslinking reaction is initiated after sufficient reflow at high temperature, whereby a favorable planarization film is formed. In contrast, in Comparative Example 3, the crosslinking agent exhibits low crosslinking initiation temperature, and thus sufficient reflow properties are not achieved, resulting in poor planarity.

TABLE 3

| | | | | DENSE/OPEN |
|---|---|---|---|---|
| | | DENSE | OPEN | Difference in |
| | | Thickness | Thickness | coating level |
| | | (nm) | (nm) | (nm) |
| Example 1 | 170° C./60s + | 53 | 97 | 44 |
| | 500 mJ | | | |
| | @ 172 nm + | | | |
| | 160° C./60s | | | |
| Example 2 | 170° C./60s + | 79 | 95 | 16 |
| | 500 mJ | | | |
| | @ 172 nm + | | | |
| | 160° C./60s | | | |
| Example 3 | 300° C./60s | 156 | 198 | 42 |
| Example 4 | 300° C./60s | 178 | 202 | 24 |
| Comparative | 215° C./60s | 134 | 200 | 66 |
| Example 3 | | | | |

### INDUSTRIAL APPLICABILITY

Since the multi-level substrate coating composition of the present invention contains a furyl group, the multi-level substrate coating composition can be stably purified with an ion-exchange resin during synthesis of the composition, as compared with the case of a conventional composition containing an epoxy group. Finally, the multi-level substrate coating composition exhibits high purity. The multi-level substrate coating composition achieve sufficient filling onto a pattern and can be used for forming a coating film having planarity on a substrate.

1. A multi-level substrate coating composition comprising a compound (A) serving as a main agent, and a solvent, wherein the compound (A) has a partial structure of the following Formula (A-1), (A-2), or (A-3): 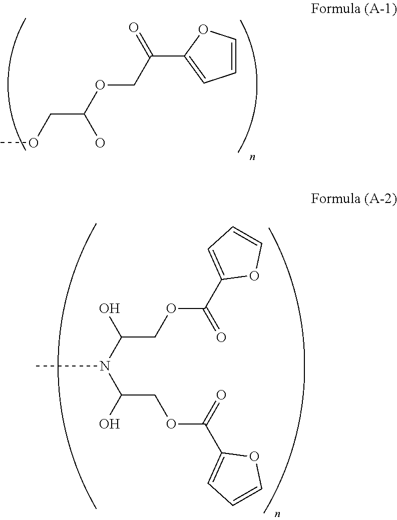
(wherein a broken line is a bond to an aromatic ring; the aromatic ring is an aromatic ring forming a polymer skeleton or an aromatic ring forming a monomer; and n is an integer of 1 or 2) 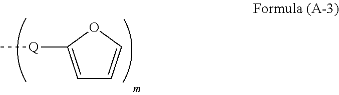
(wherein a chain line is a bond to a carbon chain, alicyclic carbon ring, or aromatic ring forming a polymer skeleton; Q is a single bond, or an organic group having an ether bond, an ester bond, a urethane bond, a C₁₋₃ alkylene bond, or an amide bond; m is 1; and Formula (A-3) does not include Formula (A-1)), and the composition is cured by photoirradiation or heating.

2. The multi-level substrate coating composition according to claim 1, wherein the aromatic ring is a benzene ring, a naphthalene ring, or an anthracene ring.

3. The multi-level substrate coating composition according to claim 1, wherein the polymer containing the aromatic ring is a polymer having a hydroxyaryl novolac structure in which a hydroxyl group is substituted with a partial structure of Formula (A-1) or (A-2).

4. The multi-level substrate coating composition according to claim 1, wherein the monomer containing the aromatic ring is a monomer prepared by substitution of a hydroxyl group of the aromatic ring with a partial structure of Formula (A-1) or (A-2).

5. The multi-level substrate coating composition according to claim 1, wherein the composition further comprises an acid generator.

6. The multi-level substrate coating composition according to claim 1, wherein the composition further comprises a surfactant.

7. A method for producing a coated substrate, the method comprising a step (i) of applying the multi-level substrate coating composition according claim 1 to a multi-level substrate; and a step (ii) of exposing the composition applied in the step (i) to light or heating the composition.

8. The method for producing a coated substrate according to claim 7, wherein the method further comprises a step (ia) of heating the multi-level substrate coating composition on the multi-level substrate at a temperature of 70° C. to 400° C. for 10 seconds to five minutes after the step (i) and before the light exposure step (ii).

9. The method for producing a coated substrate according to claim 7, wherein light used for the light exposure in the step (ii) has a wavelength of 150 nm to 700 nm.

10. The method for producing a coated substrate according to claim 7, wherein the dose of exposure light is 10 mJ/cm² to 5,000 mJ/cm² in the step (ii).

11. The method for producing a coated substrate according to claim 7, wherein the composition is heated at a temperature of 100° C. to 500° C. in the step (ii).

12. The method for producing a coated substrate according to claim 7, wherein the multi-level substrate has an open area (non-patterned area) and a patterned area of DENSE (dense) and ISO (coarse), and the pattern has an aspect ratio of 0.1 to 100.

13. The method for producing a coated substrate according to claim 7, wherein the multi-level substrate has an open area (non-patterned area) and a patterned area of DENSE (dense) and ISO (coarse), and the difference in coating level (Bias) between the open area and the patterned area is 1 nm to 50 nm.

14. A method for producing a semiconductor device, the method comprising a step of forming, on a multi-level semiconductor substrate, an underlayer film from the multi-level substrate coating composition according to claim 1; a step of forming a resist film on the underlayer film; a step of irradiating the resist film with light or electron beams or heating the resist film during or after irradiation with light or electron beams, and then developing the resist film, to thereby form a resist pattern; a step of etching the underlayer film with the formed resist pattern; and a step of processing the semiconductor substrate with the patterned underlayer film.

15. The method for producing a semiconductor device, the method comprising a step of forming, on a multi-level semiconductor substrate, an underlayer film from the multi-level substrate coating composition according to claim 1; a step of forming a resist film on the underlayer film; a step of irradiating the resist film with light or electron beams or heating the resist film during or after irradiation with light or electron beams, and then developing the resist film, to thereby form a resist pattern; a step of etching the underlayer film with the formed resist pattern; and a step of processing the semiconductor substrate with the patterned underlayer film, wherein the underlayer film forming step comprises a step (i) of applying the multi-level substrate coating composition according to claim 1 to the multi-level substrate; and a step (ii) of exposing the composition applied in the step (i) to light or heating the composition.

16. The method for producing a semiconductor device according to claim 15, wherein the method further comprises a step (ia) of heating the multi-level substrate coating composition on the multi-level substrate at a temperature of 70° C. to 400° C. for 10 seconds to five minutes after the step (i) and before the light exposure step (ii).

17. The method for producing a semiconductor device according to claim 15, wherein light used for the light exposure in the step (ii) has a wavelength of 150 nm to 700 nm.

18. The method for producing a semiconductor device according to claim 15, wherein the dose of exposure light is 10 mJ/cm² to 5,000 mJ/cm² in the step (ii).

19. The method for producing a semiconductor device according to claim 15, wherein the composition is heated at a temperature of 100° C. to 500° C. in the step (ii).

20. The method for producing a semiconductor device according to claim 14, wherein the multi-level substrate has an open area (non-patterned area) and a patterned area of DENSE (dense) and ISO (coarse), and the pattern has an aspect ratio of 0.1 to 100.

21. The method for producing a semiconductor device according to claim 14, wherein the multi-level substrate has an open area (non-patterned area) and a patterned area of DENSE (dense) and ISO (coarse), and the underlayer film formed from the multi-level substrate coating composition has a difference in coating level (Bias) between the open area and the patterned area of 1 nm to 50 nm.

22. A method for producing a semiconductor device, the method comprising a step of forming, on a multi-level semiconductor substrate, an underlayer film from the multi-level substrate coating composition according to claim 1; a step of forming a hard mask on the underlayer film; a step of forming a resist film on the hard mask; a step of irradiating the resist film with light or electron beams or heating the resist film during or after irradiation with light or electron beams, and then developing the resist film, to thereby form a resist pattern; a step of etching the hard mask with the formed resist pattern; a step of etching the underlayer film with the patterned hard mask; and a step of processing the semiconductor substrate with the patterned underlayer film.

23. The method for producing a semiconductor device, the method comprising a step of forming, on a multi-level semiconductor substrate, an underlayer film from the multi-level substrate coating composition according to claim 1; a step of forming a hard mask on the underlayer film; a step of forming a resist film on the hard mask; a step of irradiating the resist film with light or electron beams or heating the resist film during or after irradiation with light or electron beams, and then developing the resist film, to thereby form a resist pattern; a step of etching the hard mask with the formed resist pattern; a step of etching the underlayer film with the patterned hard mask; and a step of processing the semiconductor substrate with the patterned underlayer film, wherein the underlayer film forming step comprises a step (i) of applying the multi-level substrate coating composition according to claim 1 to the multi-level substrate; and a step (ii) of exposing the composition applied in the step (i) to light or heating the composition.

24. The method for producing a semiconductor device according to claim 23, wherein the method further comprises a step (ia) of heating the multi-level substrate coating composition on the multi-level substrate at a temperature of 70° C. to 400° C. for 10 seconds to five minutes after the step (i) and before the light exposure step (ii).

25. The method for producing a semiconductor device according to claim 23, wherein light used for the light exposure in the step (ii) has a wavelength of 150 nm to 700 nm.

26. The method for producing a semiconductor device according to claim 23, wherein the dose of exposure light is 10 mJ/cm² to 5,000 mJ/cm² in the step (ii).

27. The method for producing a semiconductor device according to claim 23, wherein the composition is heated at a temperature of 100° C. to 500° C. in the step (ii).

28. The method for producing a semiconductor device according to claim 22, wherein the multi-level substrate has an open area (non-patterned area) and a patterned area of DENSE (dense) and ISO (coarse), and the pattern has an aspect ratio of 0.1 to 100.

29. The method for producing a semiconductor device according to claim 22, wherein the multi-level substrate has an open area (non-patterned area) and a patterned area of DENSE (dense) and ISO (coarse), and the underlayer film formed from the multi-level substrate coating composition has a difference in coating level (Bias) between the open area and the patterned area of 1 nm to 50 nm.
